(19) United States
(12) Patent Application Publication
(10) Pub. No.: US 2019/0243194 A1
(43) Pub. Date: Aug. 8, 2019

(54) ACTIVE MATRIX SUBSTRATE AND METHOD FOR MANUFACTURING SAME

(71) Applicant: Sharp Kabushiki Kaisha, Sakai City, Osaka (JP)

(72) Inventor: Kuniaki OKADA, Sakai City (JP)

(21) Appl. No.: 16/329,879

(22) PCT Filed: Aug. 29, 2017
(86) PCT No.: PCT/JP2017/030892

§ 371 Date: Mar. 1, 2019

(30) Foreign Application Priority Data
Sep. 2, 2016 (JP) 2016-171548

(51) Int. Cl. G02F 1/1362; H01L 27/12; G02F 1/1368

(52) U.S. Cl. CPC G02F 1/136209; H01L 27/1225; G02F 1/134363; G02F 1/1368; H01L 27/1274

(57) ABSTRACT

An active matrix substrate (100) has the following: a substrate (12); a first thin film transistor (10A) that is supported on the substrate (12) and that has a first semiconductor layer (13A) including crystalline silicon; a second thin film transistor (10B) that is supported on the substrate (12) and that has a second semiconductor layer (17) including an oxide semiconductor; and a third semiconductor layer (13B) including silicon, which is disposed on the substrate (12) side of the second semiconductor layer (17) of the second thin film transistor (10B), with a first insulating layer (14) interposed between the third semiconductor layer and the second semiconductor layer.

### TECHNICAL FIELD

The present invention relates to an active matrix substrate and a method for manufacturing same, and more particularly, relates to an active matrix substrate suitably used for active matrix display devices such as a liquid crystal display device and an organic EL display device and a method for manufacturing same.

### BACKGROUND ART

In an active matrix substrate for a display device, for example, a thin film transistor (hereinafter, referred to as “TFT”) is provided for each pixel as a switching element. In the present description, such a TFT will be referred to as “pixel TFT”. As the pixel TFT, conventionally, an amorphous silicon TFT with an amorphous silicon film as the semiconductor layer and a crystalline silicon TFT with a crystalline silicon film such as a polycrystalline silicon film as the semiconductor layer have been widely used.

There are also cases where part or the whole of a peripheral driving circuit is integrally formed on the same substrate as the pixel TFT. Such an active matrix substrate is called a driver monolithic active matrix substrate. On the driver monolithic active matrix substrate, the peripheral driving circuit is provided in a region (a non-display region or a frame region) other than the region (display region) including a plurality of pixels. The pixel TFT and the TFT (TFT for a circuit) constituting the driving circuit can be formed by using the same semiconductor film. As this semiconductor film, for example, a polycrystalline silicon film with a high field effect mobility is used.

As a material for the TFT semiconductor film, a TFT using an oxide semiconductor has been put to practical use. As the oxide semiconductor, for example, an In—Ga—Zn—O based semiconductor whose principal components are indium, gallium, zinc and oxygen is used. Such a TFT is referred to as “oxide semiconductor TFT”. The oxide semiconductor has a higher mobility than amorphous silicon. For this reason, the oxide semiconductor TFT is capable of operating at a higher speed than the amorphous silicon TFT. Moreover, the oxide semiconductor is applicable to a device that requires a large area since it is formed by a simpler process than the polycrystalline silicon film. Therefore, the pixel TFT and the circuit TFT can also be formed integrally on the same substrate by using the oxide semiconductor film.

However, no matter whether the polycrystalline silicon film or the oxide semiconductor film is used, it is difficult to fully satisfy the characteristics required for both of the pixel TFT and the circuit TFT.

On the contrary, Patent Document No. 1 discloses an active matrix liquid crystal panel provided with an oxide semiconductor TFT as the pixel TFT and a TFT the semiconductor layer of which is a non-oxide semiconductor film (for example, a crystalline silicon TFT) as the circuit TFT. On the liquid crystal panel of Patent Document No. 1, the oxide semiconductor TFT and the crystalline silicon TFT are formed on the same substrate. Patent Document No. 1 describes that display unevenness can be suppressed by using the oxide semiconductor TFT as the pixel TFT and high speed driving is enabled by using the crystalline silicon TFT as the circuit TFT.

### CITATION LIST

### Patent Literature

Patent Document No. 1: Japanese Laid-Open Patent Publication No. 2010-3910

### SUMMARY OF INVENTION

### Technical Problem

The oxide semiconductor TFT whose off-leak current is small is suitably used as the pixel TFT. However, there is a problem in that if external light and/or light from the backlight is incident on the oxide semiconductor layer, the threshold voltage (Vth) is shifted to the negative side to make the operation of the TFT unstable. The incidence of the external light is prevented, for example, by a black matrix (light shielding layer) provided on a counter substrate disposed so as to face the active matrix substrate with a liquid crystal layer interposed between the counter substrate and the active matrix substrate.

If a structure where a light shielding layer is provided on the backlight side of the oxide semiconductor layer is adopted in order to prevent the incidence of light from the backlight, a problem arises in that the number of manufacturing steps increases and mass productivity is deteriorated. Moreover, if the gate electrode disposed on the backlight side of the oxide semiconductor layer is made larger, the parasitic capacitance increases to deteriorate the TFT characteristics.

The present invention is made in order to solve the above-mentioned problem, and an object thereof is to provide an active matrix substrate where characteristic fluctuation due to light of the oxide semiconductor TFT for a pixel is suppressed while deterioration of the mass productivity and the TFT characteristics is suppressed, and a method for manufacturing same.

### Solution to Problem

An active matrix substrate according to an embodiment of the present invention has: a substrate; a first thin film transistor supported on the substrate and having a first semiconductor layer including crystalline silicon; a second thin film transistor supported on the substrate and having a second semiconductor layer including an oxide semiconductor; and a third semiconductor layer including silicon and disposed on the substrate side of the second semiconductor layer of the second thin film transistor with the first insulating layer interposed between the third semiconductor layer and the second semiconductor layer. According to the embodiment, the first semiconductor layer and the third semiconductor layer are disposed at the same level. That is, the first semiconductor layer and the third semiconductor layer are formed of the same semiconductor film, and the region of the semiconductor film where at least the first semiconductor layer is formed is crystalized.

According to the embodiment, the second thin film transistor further has a gate electrode formed on the first insulating layer and a second insulating layer covering the gate electrode on the substrate side of the second semiconductor layer, and when viewed from a normal direction of the substrate, an outer periphery of a region where the second semiconductor layer and the gate electrode overlap each other is located inside an outer periphery of the third semiconductor layer. According to the embodiment, the length of the gate electrode in the channel length direction is shorter than the length of the second semiconductor layer in the channel length direction, and/or the length of the gate electrode in the channel width direction is shorter than the length of the second semiconductor layer in the channel width direction.

According to the embodiment, when viewed from the normal direction of the substrate, an outer periphery of the second semiconductor layer is inside the outer periphery of the third semiconductor layer.

According to the embodiment, the first thin film transistor further has a gate electrode disposed so as to face the first semiconductor layer with the first insulating layer interposed between the gate electrode and the first semiconductor layer, and the gate electrode of the first thin film transistor is formed of the same conductive film as the gate electrode of the second thin film transistor.

According to the embodiment, a pixel electrode formed of a transparent conductive layer is further provided, and the pixel electrode is in direct contact with the second semiconductor layer.

According to the embodiment, the first semiconductor layer includes polycrystalline silicon, and the third semiconductor layer includes amorphous silicon or polycrystalline silicon.

According to the embodiment, the oxide semiconductor includes an In—Ga—Zn—O based semiconductor.

According to the embodiment, the second semiconductor layer includes a crystalline In—Ga—Zn—O based semiconductor.

According to the embodiment, the second semiconductor layer has a multilayer structure.

According to the embodiment, the second thin film transistor is of a channel-etch type.

A method of manufacturing an active matrix substrate according to an embodiment of the present invention is a method of manufacturing any of the above-described active matrix substrates, and includes steps of: (A) preparing the substrate; (B) depositing a semiconductor film including silicon on the substrate; (C) crystallizing at least part of the semiconductor film to form a first semiconductor film including crystalline silicon; and (D) patterning the semiconductor film to form the first semiconductor layer and the second semiconductor layer, and the step (D) includes a step of patterning the first semiconductor film to form the first semiconductor layer.

### Advantageous Effects of Invention

According to the present invention, an active matrix substrate where characteristic fluctuation due to light of the oxide semiconductor TFT for a pixel is suppressed while deterioration of the mass productivity and the TFT characteristics is suppressed, and a method for manufacturing same.

### BRIEF DESCRIPTION OF DRAWINGS

FIG. 1(a) is a schematic cross-sectional view of a TFT substrate 100 according to a first embodiment of the present invention.

FIG. 1(b) is a schematic plan view of a pixel region of the TFT substrate 100.

FIG. 2 is a schematic plan view of the entire TFT substrate 100.

FIG. 3(a) shows a schematic cross-sectional view of a second TFT 30B for a pixel of a TFT substrate 200 according to a second embodiment of the present invention.

FIG. 3(b) shows a schematic plan view of a pixel region of the TFT substrate 200.

FIG. 4(a) shows a schematic cross-sectional view of a second TFT 50B for a pixel of a TFT substrate 300 according to a third embodiment of the present invention.

FIG. 4(b) shows a schematic plan view of a pixel region of the TFT substrate 300.

### DESCRIPTION OF EMBODIMENTS

Hereinafter, referring to the drawings, structures and manufacturing methods of active matrix substrates according to embodiments of the present invention will be described. While the active matrix substrates shown below are TFT substrates used for a liquid crystal display device of an FFS (fringe field switching) mode, the active matrix substrates according to the embodiments of the present invention are not limited thereto, and are suitably used for liquid crystal display devices of different display modes (for example, a vertical alignment mode). The active matrix substrates according to the embodiments of the present invention are suitably usable further for other known active matrix display devices such as an organic EL display device.

The active matrix substrates according to the embodiments of the present invention have a first TFT having a first semiconductor layer including crystalline silicon and a second TFT having a second semiconductor layer including an oxide semiconductor, and have a third semiconductor layer including silicon and disposed on the substrate side of the second semiconductor layer of the second TFT with an insulating layer interposed between the third semiconductor layer and the second semiconductor layer. For example, the first TFT is the circuit TFT, and the second TFT is the pixel TFT. The third semiconductor layer functions as a light shielding layer that prevents light from being incident on the second semiconductor layer from the substrate side (backlight side). The third semiconductor layer which contains silicon like the first semiconductor layer can be formed of the same semiconductor film as the first semiconductor layer. Therefore, it is unnecessary to add a manufacturing step in order to form the third semiconductor layer. When a polycrystalline silicon layer is used for the first semiconductor layer, the region where the first semiconductor layer of a semiconductor film including silicon is formed is crystallized. At this time, it is unnecessary that the region where the third semiconductor layer is formed be crystallized. That is, a structure may be adopted where the first semiconductor layer is a polycrystalline silicon layer and the third semiconductor layer is an amorphous silicon layer. Since amorphous silicon absorbs light with a short wavelength (approximately 300 nm to approximately 600 nm) more efficiently than polycrystalline silicon, the effect of preventing light deterioration of the oxide semiconductor layer is high. Moreover, since only the amorphous silicon film in the region where the circuit TFT is formed (the non-display region or the frame region) is necessarily crystalized, the time required for crystallization is not increased, either. However, a crystalline silicon layer may be used as the third semiconductor layer. In the present description, the “crystalline silicon” contains at least partially crystalized silicon such as microcrystalline silicon (μC-Si) as well as polycrystalline silicon.

### First Embodiment

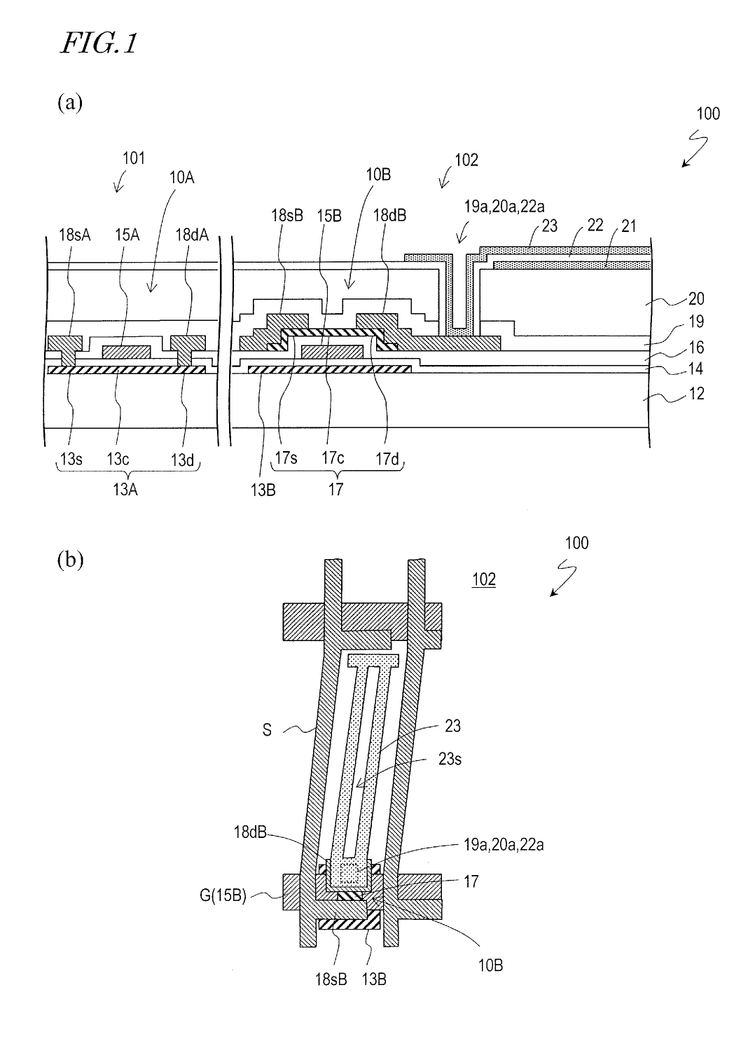

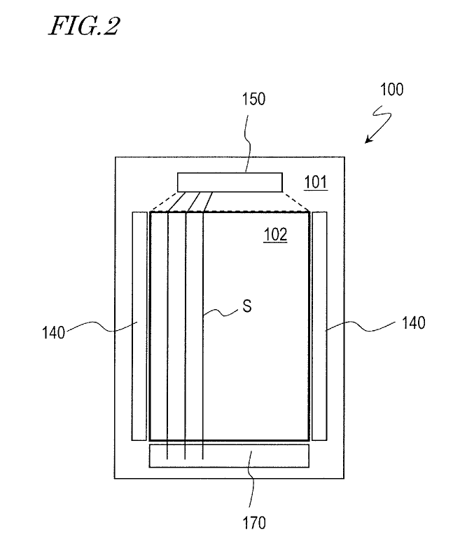

FIG. 1(a) shows a schematic cross-sectional view of an active matrix substrate 100 (hereinafter, referred to as “TFT substrate 100”) according to a first embodiment of the present invention, and FIG. 1(b) shows a schematic plan view of a pixel region of the TFT substrate 100. FIG. 2 shows a schematic plan view of the entire TFT substrate 100.

As shown in FIG. 2, the TFT substrate 100 has a display region 102 including a plurality of pixels and a region (non-display region) other than the display region 102. The non-display region includes a driving circuit formation region 101 where a driving circuit is provided. In the driving circuit formation region 101, for example, a gate driver circuit 140, a source driver circuit 150 and an inspection circuit 170 are provided.

In the display region 102, a plurality of gate bus lines (not shown) extending in the row direction and a plurality of source bus lines S extending in the column direction are formed. Although not shown, the pixels are each defined, for example, by the gate bus lines and the source bus lines S. The gate bus lines are connected to terminals of the gate driver circuit 140, respectively, and the source bus lines S are connected to terminals of the source driver circuit 150, respectively. A structure may be adopted where only the gate driver circuit 140 is monolithically formed on the TFT substrate 100 and a driver IC is mounted as the source driver circuit 150.

In the TFT substrate 100, as shown in FIG. 1(a), in the driving circuit formation region 101, a first TFT 10A is formed as the circuit TFT, and at each pixel in the display region 102, a second TFT 10B is formed as the pixel TFT.

The TFT substrate 100 is provided with a substrate 12, and the first TFT 10A and the second TFT 10B formed on the substrate 12. The substrate 12 is, for example, a glass substrate, and an underlay film (not shown) may be formed on the substrate 12. When an underlay film is formed, circuit elements such as the first TFT 10A and the second TFT 10B are formed on the underlay film. Although not specifically limited, the underlay film is an inorganic insulating film, and is, for example, a silicon nitride (SiNx) film, a silicon oxide (SiOx) film, or a laminated film with a silicon nitride film as the lower layer and a silicon oxide film as the upper layer.

The first TFT 10A has an active region mainly including crystalline silicon. The second TFT 10B has an active region mainly including an oxide semiconductor. The first TFT 10A and the second TFT 10B are integrally formed on the substrate 12. The “active region” referred to here indicates a region of the semiconductor layer of the TFT where a channel is formed.

The first TFT 10A has a crystalline silicon semiconductor layer (for example, a low-temperature polysilicon layer) 13 formed on the substrate 12, a first insulating layer 14 covering the crystalline silicon semiconductor layer 13A, and a gate electrode 15A provided on the first insulating layer 14. The part of the first insulating layer 14, which is located between the crystalline silicon semiconductor layer 13A and the gate electrode 15A, functions as the gate insulating film of the first TFT 10A. The crystalline silicon semiconductor layer 13A has a region (active region) 13c where a channel is formed, and a source region 13s and a drain region 13d located on both sides of the active region, respectively. In this example, of the crystalline silicon semiconductor layer 13A, the part overlapping the gate electrode 15A with the first insulating layer 14 interposed between the part and the gate electrode 15A is the active region 13c. The first TFT 10A also has a source electrode 18sA and a drain electrode 18dA connected to the source region 13s and the drain region 13d, respectively. The source electrode 18sA and the drain electrode 18dA may be provided on an interlayer insulating film (here, a second insulating layer 16) covering the gate electrode 15A and the crystalline silicon semiconductor layer 13A and be connected to the crystalline silicon semiconductor layer 13A within a contact hole formed in the interlayer insulating film. As described above, the first TFT 10A is a top gate TFT.

The second TFT 10B is a bottom gate TFT, and has a gate electrode 15B, the second insulating layer 16 covering the gate electrode 15B and an oxide semiconductor layer 17 disposed on the second insulating layer 16. Here, the gate electrode 15B is provided on a silicon semiconductor layer 13B formed on the substrate 12 and the first insulating layer 14 covering the silicon semiconductor layer 13B. As illustrated, the silicon semiconductor layer 13B is formed at the same level as the crystalline silicon semiconductor layer 13A of the first TFT 10A (that is, on the surface of the substrate 12), and the first insulating layer 14 as the gate insulating film of the first TFT 10A is extended to the region where the second TFT 10B is formed. The gate electrode 15B is formed of the same conductive film as the gate electrode 15A of the first TFT 10A.

The part of the second insulating layer 16, which is located between the gate electrode 15B and the oxide semiconductor layer 17, functions as the gate insulating film of the second TFT 10B. When the second insulating layer 16 has a two-layer structure of, for example, a hydrogen donating lower layer and an oxygen donating upper layer, the following advantages are produced:

In a heating treatment described later, hydrogen is supplied from the hydrogen donating lower layer of the second insulating layer 16 to the crystalline silicon semiconductor layer 13A, so that crystal deficiency that occurs on the crystalline silicon semiconductor layer 13A can be reduced. Moreover, since oxygen is supplied from the oxygen donating upper layer of the second insulating layer 16 to the oxide semiconductor layer 17, the oxygen loss that occurs on the oxide semiconductor layer 17 can be reduced. Consequently, the deterioration of the crystalline silicon semiconductor layer 13A and the oxide semiconductor layer 17 as the active layers of the thin film transistors 10A and 10B can be suppressed to improve the reliability of the thin film transistors 10A and 10B. Moreover, if the oxygen donating upper layer is disposed so as to be in contact with the oxide semiconductor layer 17, the oxygen loss of the oxide semiconductor layer 17 can be more effectively reduced.

The hydrogen donating lower layer may be, for example, a silicon nitride (SiNx) layer or a silicon nitride oxide (SiNxLy: x>y) layer mainly including silicon nitride. The oxygen donating upper layer may be, for example, a silicon oxide (SiOx) layer or a silicon oxide nitride (SiOxNy: x>y) layer mainly including silicon oxide. In particular, if an SiOx layer is used as the oxygen donating upper layer, an excellent channel interface can be formed on the interface with the oxide semiconductor layer 17, so that an advantage is obtained in that the reliability of the second thin film transistor 10B can be further improved.

The oxide semiconductor layer 17 has a region (active region) 17c where a channel is formed, and a source contact region 17s and a drain contact region 17d located on both sides of the active region, respectively. In this example, of the oxide semiconductor layer 17, the part overlapping the gate electrode 15B with the second insulating layer 16 interposed between the part and the gate electrode 15B is the active region 17c. Moreover, the second TFT 10B further has a source electrode 18sB and a drain electrode 18dB connected to the source contact region 17s and the drain contact region 17d, respectively.

Here, as shown in FIG. 1(b), the gate electrode 15B is formed as a part of a gate bus line G. That is, of the gate bus line G, the part overlapping the oxide semiconductor layer 17 corresponds to the gate electrode 15B, and the width direction of the gate bus line G corresponds to the channel length direction of the second TFT 10B. The source electrode 18sB is formed integrally with the source bus line S and is formed so as to diverge in the row direction from the source bus line S extending in the column direction.

When viewed from the normal direction of the substrate 12, the outer periphery of the region (the active region 17c) where the oxide semiconductor layer 17 and the gate electrode 15B overlap each other is located inside the outer periphery of the silicon semiconductor layer 13B. Therefore, the silicon semiconductor layer 13B can sufficiently shield from light at least the active region 17c of the oxide semiconductor layer 17. As a consequence, it is unnecessary to shield the active region 17c from light by the gate electrode 15B, so that the length of the gate electrode 15B in the channel length direction may be shorter than the length of the oxide semiconductor layer 17 in the channel length direction. Moreover, on a TFT where the dispositions and/or configurations of the gate electrode, the semiconductor layer, the source electrode and the drain electrode are different, the length of the gate electrode in the channel width direction may be shorter than the length of the silicon semiconductor layer in the channel width direction. As described above, if a structure where light shielding is performed by the silicon semiconductor layer 13B is adopted, it is unnecessary that the gate electrode 15B be large, so that the TFT characteristics are never deteriorated with the increase in the parasitic capacitance associated with the gate electrode 15B.

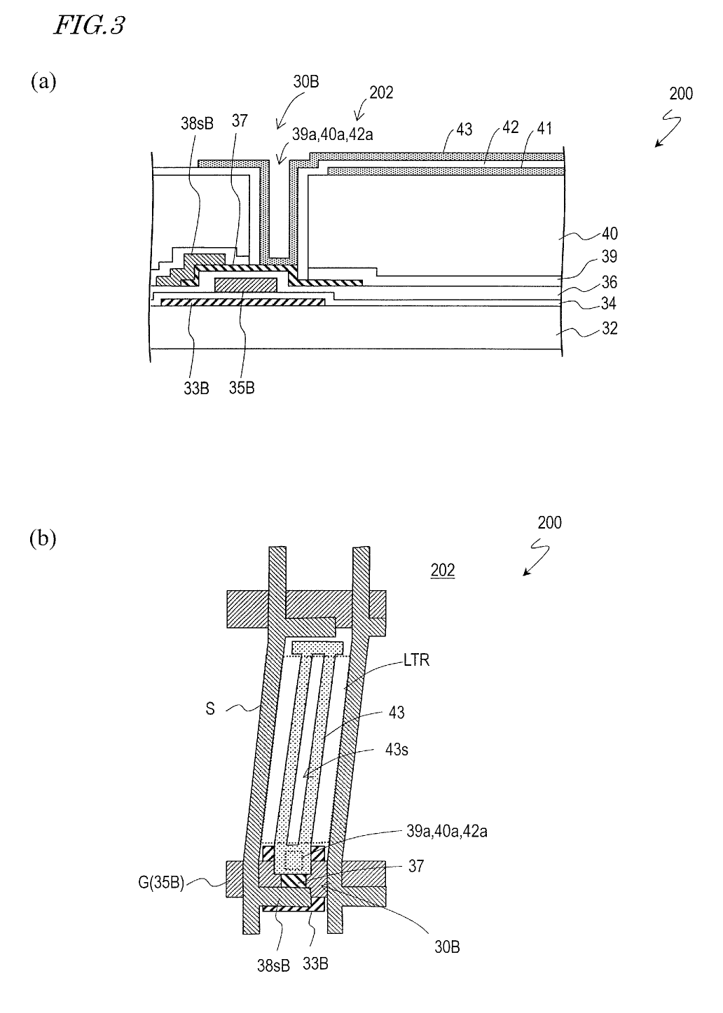

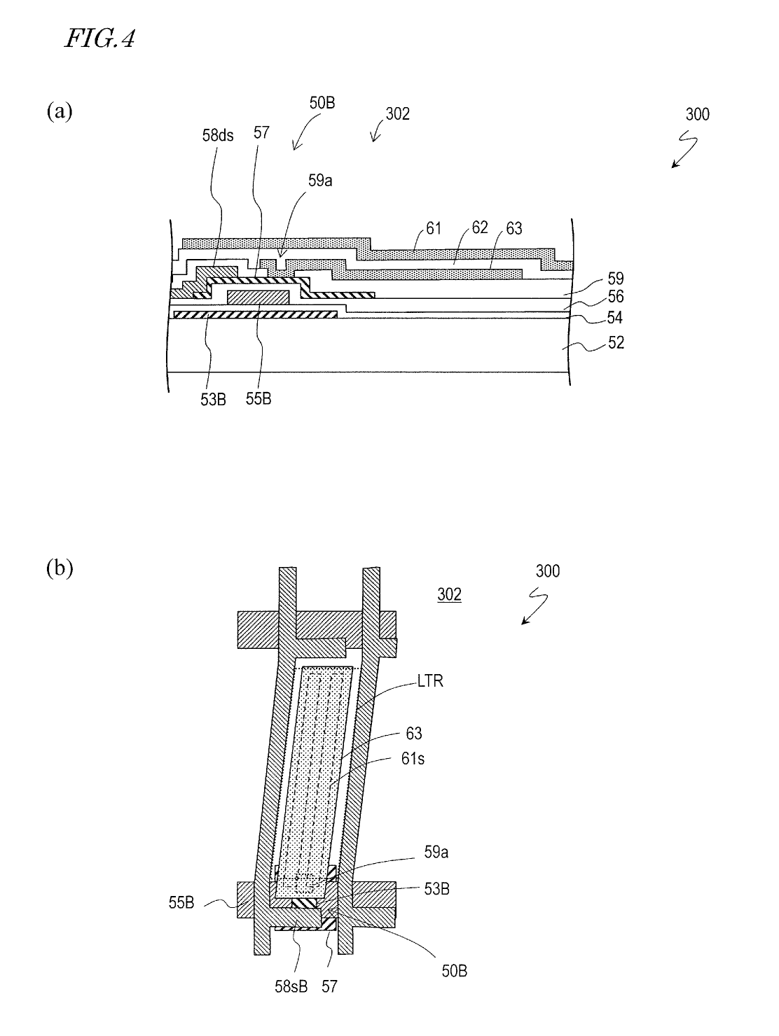

To fully deliver the light shielding effect by the silicon semiconductor layer 13B, it is preferable to dispose the silicon semiconductor layer 13B so that the outer periphery of the oxide semiconductor layer 17 is located inside the outer periphery of the silicon semiconductor layer 13B when viewed from the normal direction of the substrate 12. However, various variations are known as dispositions and/or configurations of the gate electrode, semiconductor layer, source electrode and drain electrode of the TFT and it is not always necessary that the outer periphery of the oxide semiconductor layer be located inside the outer periphery of the silicon semiconductor layer (for example, see FIG. 3 and FIG. 4). It is necessary only that the silicon semiconductor layer for light shielding can sufficiently shield at least the active region of the oxide semiconductor layer from light.

The TFTs 10A and 10B are covered with a third insulating layer 19 and a fourth insulating layer 20. On the fourth insulating layer 20, a common electrode 21, a fifth insulating layer 22 and a pixel electrode 23 are formed in this order. The pixel electrode 23 has a slit 23s. More than one slit 23s may be provided. The common electrode 21 and the pixel electrode 23 are formed of a transparent conductive layer. The transparent conductive layer can be formed of, for example, ITO (indium tin oxide), IZO (indium zinc oxide, “IZO” is a trademark) or ZnO (zinc oxide).

The pixel electrode 23 is connected to the drain electrode 18dB inside openings 19a, 20a and 22a formed in the third insulating layer 19, the fourth insulating layer 20 and the fifth insulating layer 22. The common electrode 21 is provided so as to be common to a plurality of pixels, is connected to non-illustrated common wiring and/or a common electrode terminal portion, and is supplied with a common voltage (Vcom).

The oxide semiconductor included in the oxide semiconductor layer 17 may be an amorphous oxide semiconductor or may be a crystalline oxide semiconductor having a crystalline part. Examples of the crystalline oxide semiconductor include a multicrystalline oxide semiconductor, a microcrystalline oxide semiconductor, and a crystalline oxide semiconductor where the c axis is oriented substantially vertically to the layer surface.

The oxide semiconductor layer 17 may have a multilayer structure of two or more layers. When the oxide semiconductor layer 17 has a multilayer structure, the oxide semiconductor layer 17 may include a non-crystalline oxide semiconductor layer and a crystalline oxide semiconductor layer. Alternatively, it may include a plurality of crystalline oxide semiconductor layers having different crystal structures. Moreover, it may include a plurality of non-crystalline oxide semiconductor layers. When the oxide semiconductor layer 17 has a two-layer structure including an upper layer and a lower layer, it is preferable that the energy gap of the oxide semiconductor contained in the upper layer be larger than the energy gap of the oxide semiconductor contained in the lower layer. However, when the difference between the energy gaps of these layers is comparatively small, the energy gap of the oxide semiconductor of the lower layer may be larger than the energy gap of the oxide semiconductor of the upper layer.

The structure and the like of the oxide semiconductor layer having the materials, structures, forming methods and multilayer structures of the non-crystalline oxide semiconductor and the above-described crystalline oxide semiconductors are described, for example, in Japanese Laid-Open Patent Publication No. 2014-007399. For reference, all the contents of the disclosure of Japanese Laid-Open Patent Publication No. 2014-007399 are applied to the present description.

The oxide semiconductor layer 17 may contain, for example, at least one kind of In, Ga and Zn. In the present embodiment, the oxide semiconductor layer 17 contains, for example, an In—Ga—Zn—O based semiconductor (for example, indium gallium zinc oxide). Here, the In—Ga—Zn—O based semiconductor is a ternary oxide of In (indium), Ga (gallium) and Zn (zinc), and the ratio (composition ratio) among In, Ga and Zn is not specifically limited and includes, for example, In:Ga:Zn=2:2:1, In:Ga:Zn=1:1:1 and In:Ga:Zn=1:1:2. The oxide semiconductor layer 17 as described above can be formed of an oxide semiconductor film including an In—Ga—Zn—O based semiconductor.

The In—Ga—Zn—O based semiconductor may be amorphous or may be crystalline. It is preferable that the semiconductor of the crystalline In—Ga—Zn—O based semiconductor be a crystalline In—Ga—Zn—O based semiconductor where the c axis is oriented substantially vertically to the layer surface.

The crystal structure of the crystalline In—Ga—Zn—O based semiconductor is disclosed, for example, in the above-described Japanese Laid-Open Patent Publication No. 2014-007399, Japanese Laid-Open Patent Publication No. 2012-134475 and Japanese Laid-Open Patent Publication No. 2014-209727. For reference, all the contents of the disclosures of Japanese Laid-Open Patent Publication No. 2012-134475 and Japanese Laid-Open Patent Publication No. 2014-209727 are adopted to the present description. The TFT having the In—Ga—Zn—O based semiconductor layer is suitably used as the pixel TFT (TFT provided at each pixel) since it has a high mobility (beyond twenty times that of the a-Si TFT) and a low leak current (less than one-hundredth of that of the a-Si TFT).

The oxide semiconductor layer 17 may include a different oxide semiconductor instead of the In—Ga—Zn—O based semiconductor. It may contain, for example, an In—Sn—Zn—O based semiconductor (for example, In₂0₃-Sn0₂-Zn0; InSnZnO). The In—Sn—Zn—O based semiconductor is a ternary oxide of In (indium), Sn (tin) and Zn (zinc). Alternatively, the oxide semiconductor layer 17 may contain an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, a CdO (cadmium oxide), an Mg—Zn—O based semiconductor, an In—Ga—Sn—O based semiconductor, an In—Ga—O based semiconductor, a Zr—In—Zn—O based semiconductor, an Hf—In—Zn—O based semiconductor, an Al—Ga—Zn—O based semiconductor, a Ga—Zn—O based semiconductor or the like.

A method for manufacturing the TFT substrate according to the embodiment of the present invention includes: a step of preparing a substrate; a step of depositing a semiconductor film including silicon on the substrate; a step of crystalizing at least part of the semiconductor film to thereby form a semiconductor film including crystalline silicon; and a step of patterning the semiconductor film including silicon to thereby form a crystalline silicon semiconductor layer of a first TFT and a silicon semiconductor layer for light shielding which step includes a step of patterning the crystalline silicon semiconductor film to thereby form a crystalline silicon semiconductor layer of the first TFT.

The TFT substrate 100 can be manufactured, for example, as follows:

First, the substrate 12 is prepared. For the substrate 12, for example, various substrates such as a glass substrate, a resin plate and a resin film may be used.

Then, a non-crystalline silicon (a-Si) film is deposited on the substrate 12. The deposition of the a-Si film may be performed by a known method such as a plasma CVD (chemical vapor deposition) method or a sputtering method. The thickness of the a-Si film is, for example, not less than 30 nm and not more than 70 nm.

The region of the a-Si film where at least the silicon semiconductor layer 13A of the first TFT 10A is formed is crystalized. The crystallization can be performed, for example, by applying excimer laser light to the a-Si film. The region where the silicon semiconductor layer 13B disposed on the lower layer of the second TFT 10B does not need to be crystalized and may be left non-crystalline.

By patterning a silicon semiconductor film at least part of which is crystalized, the crystalline silicon semiconductor layer 13A and the silicon semiconductor layer 13B that are insular are formed.

Thereafter, a first insulating layer (thickness: for example, not less than 50 nm and not more than 130 nm) 14 is formed so as to cover the crystalline silicon semiconductor layer 13A and the silicon semiconductor layer 13B.

Then, after the gate conductive film (thickness: not less than 200 nm and not more than 500 nm) is formed, this is patterned to thereby obtain the gate electrode 15A of the first thin film transistor 10A, the gate electrode 15B of the second thin film transistor 10B, gate wiring and the like. The material of the gate conductive film is not specifically limited, and a film including a metal such as aluminum (Al), tungsten (W), molybdenum (Mo), tantalum (Ta), chromium (Cr), titanium (Ti), copper (Cu) or the like and an alloy thereof may be used as appropriate. Moreover, a laminated film (an upper layer/lower layer) formed of a lamination of these films may be used. For example, a laminated film of W (thickness: 300 nm)/TaN (thickness: 30 nm) can be suitably used. The patterning method is not specifically limited, and known photolithography and dry etching may be used.

Thereafter, with the gate electrode 15A as the mask, an impurity is injected into the crystalline silicon semiconductor layer 13A to form the source region 13s and the drain region 13d. The region of the crystalline silicon semiconductor layer 13A where no impurity is injected is the active region (channel region) 13c.

Then, the second insulating layer (thickness: for example, not less than 180 nm and not more than 550 nm) 16 that covers the first insulating layer 14 and the gate electrodes 15A and 15B is formed. In this example, as the second insulating layer 16, a laminated film having a hydrogen donating lower layer and an oxygen donating upper layer is formed. For example, an SiO₂ layer (thickness: 50 nm)/SiNx layer (thickness: 325 nm) is formed. The thickness of the silicon nitride (SiNx) layer is, for example, not less than 150 nm and not more than 450 nm. The silicon nitride layer can be formed, for example, by the CVD method under a condition where the composition is Si₃N₄. The thickness of the silicon oxide (SiOx) is, for example, not less than 30 nm and not more than 100 nm. The silicon oxide layer can be formed, for example, by the CVD method under a condition where the composition is SiO₂.

The second insulating layer 16 includes a part that functions as the interlayer insulating film of the first thin film transistor 10A and a part that functions as the gate insulating film of the second thin film transistor 10B. The hydrogen donating lower layer is effective in the hydrogen substitution of the unpaired bond caused in the crystalline silicon semiconductor layer 13A. Regarding the oxygen donating upper layer, when an oxygen loss occurs in the oxide semiconductor layer 17, since the oxygen loss can be recovered by the oxygen contained in the oxygen donating upper layer, reduction in resistance due to the oxygen loss of the oxide semiconductor layer 17 can be suppressed. Moreover, since the SiOx layer is suitable for the formation of the channel interface with the oxide semiconductor layer 17, if the SiOx layer is used as the oxygen donating upper layer and disposed so as to be in contact with the active region 17c of the oxide semiconductor layer 17, an excellent channel interface is obtained. Moreover, the second insulating layer 16 only necessarily has a hydrogen donating layer and an oxygen donating layer present on the oxide semiconductor layer 17 side thereof, and may have a multilayer structure of three or more layers.

Then, the oxide semiconductor layer 17 is formed in the display region 102. Specifically, first, a non-crystalline oxide semiconductor film is formed on the second insulating layer 16, for example, by the sputtering method. In this example, as the non-crystalline oxide semiconductor film, for example, an In—Ga—Zn-O non-crystalline semiconductor film (for example, with a thickness of 50 nm) is used. The thickness of the non-crystalline oxide semiconductor film is, for example, not less than 40 nm and not more than 120 nm. Thereafter, patterning of the non-crystalline oxide semiconductor film is performed to obtain an insular non-crystalline oxide semiconductor layer.

The non-crystalline oxide semiconductor film may be crystalized as required. For example, after the above-described patterning step, a heating treatment is performed, for example, at a temperature of not less than 350 degrees C. and not more than 550 degrees C., preferably, not less than 400 degrees C. and not more than 500 degrees C. This heating treatment may be performed, for example, in a nitrogen atmosphere, a mixing atmosphere of nitrogen and oxygen or an oxygen atmosphere. Since the reduction reaction of the oxygen semiconductor is avoided, the hydrogen atmosphere is not preferable and an inert gas or an oxidation atmosphere is preferable. Thereby, the non-crystalline oxide semiconductor layer is crystalized, so that a crystalline oxide semiconductor layer (in this example, a crystalline In—Ga—Zn—O based semiconductor layer) is obtained. Along therewith, hydrogen is supplied from the second insulating layer 16 (mainly, the hydrogen donating lower layer) to the crystalline silicon semiconductor layer 13A, so that at least part of the silicon unpaired bond present inside the crystalline silicon semiconductor layer 13A is terminated by hydrogen. The heating treatment with the aim of crystallization and hydrogen termination may be performed prior to the patterning of the non-crystalline oxide semiconductor film.

Then, in the first insulating layer 14 and the second insulating layer 16, a contact hole that reaches the source region 13s and the drain region 13d of the crystalline silicon semiconductor layer 13A is formed. Thereafter, the source electrode 18sA and the drain electrode 18dA of the first thin film transistor 10A and the source electrode 18sB and the drain electrode 18dB of the second thin film transistor 10B are formed.

Specifically, first, in the contact hole, a conductive film for the source is formed, for example, by the sputtering method on the second insulating layer 16 and the oxide semiconductor layer 17. Subsequently, patterning of the conductive film for the source is performed. Thereby, the source electrode 18sA and the drain electrode 18dA that are in contact with the source region 13s and the drain region 13d of the crystalline silicon semiconductor layer 13A, the source electrode 18sB and the drain electrode 18dB that are in contact with the surface of the oxide semiconductor layer 17, and a source bus line (not shown) are formed. Of the oxide semiconductor layer 17, the parts that are in contact with the source electrode 18sB and the drain electrode 18dB are the source contact region 17s and the drain contact region 17d, respectively. Of the oxide semiconductor layer 17, the part overlapping the gate electrode 15B (with the second insulating layer 16 interposed between the part and the gate electrode 15B) and located between the source contact region 17s and the drain contact region 17d is the active region 17c.

The conductive film for the source may be, for example, an aluminum film. Alternatively, it may be a laminated film having a barrier metal film (for example, a Ti film or an Mo film) on the upper layer and/or the lower layer of the aluminum film. The material of the conductive film for the source is not specifically limited. As the conductive film for the source, a film may be used as appropriate that contains a metal such as aluminum (Al), tungsten (W), molybdenum (Mo), tantalum (Ta), copper (Cu), chromium (Cr) or titanium (Ti) or an alloy thereof, or a metallic nitride thereof. Moreover, a laminated layer formed of a lamination of these films may be used. For example, a laminated film Ti (thickness: 100 nm)/Al (thickness: 200 nm)/Ti (thickness: 30 nm) where a Ti film, an Al film and a Ti film are laminated in this order may be used. In this manner, the first thin film transistor 10A and the second thin film transistor 10B are formed.

Then, a passivation film (thickness: for example, not less than 150 nm and not more than 700 nm) 19 and the fourth insulating layer 20 are formed so as to cover the first thin film transistor 10A and the second thin film transistor 10B. For example, the third insulating layer 19 is formed so as to be in contact with the surface of the active region 17c of the oxide semiconductor layer 17. At this time, it is preferable that the third insulating layer 19 be a laminated film having a lower layer formed of an SiOx film (thickness: for example, not less than 100 nm and not more than 400 nm) and an upper layer formed of an SiNx film (thickness: for example, not less than 50 nm and not more than 300 nm). In such a case, it is preferable that the lower layer of the third insulating layer 19 be an SiOx film since it constitutes the back channel of the second thin film transistor 10B. It is preferable that the upper layer be an SiNx film with a high passivation effect for the protection from moisture and impurities. The upper layer may be omitted. The material of the third insulating layer 19 is not limited thereto, and a combination of SiON, SiNO and the like may be used.

The fourth insulating layer 20 is formed on the third insulating layer 19, for example, by application. The fourth insulating layer 20 may be an organic insulating layer or may be an insulating layer formed of, for example, an acrylic transparent resin having positive photosensitivity. When an organic insulating layer is used, a planarization effect can be obtained. The fourth insulating layer 20 may be formed, for example, by using SiO₂. The thickness of the fourth insulating layer 20 is, for example, 2 μm.

Thereafter, the openings 19a and 20a to expose the drain electrode 18dB of the second thin film transistor 10B are formed in the third insulating layer 19 and the fourth insulating layer 20 by photolithography.

Then, the transparent common electrode 21 is formed on the fourth insulating layer 20. The common electrode 21 can be formed by using a transparent conductive film such as an ITO (indium tin oxide) film, an IZO film or a ZnO film (zinc oxide film). For example, the common electrode 21 is formed by using an IZO film with a thickness of 100 nm. The common electrode 21 may be formed substantially on the entire area of the display region 102 except for, for example, the regions located on the opening 19a of the third insulating layer and the opening 20a of the fourth insulating layer. In FIG. 1(b), the common electrode 21 is not shown.

Thereafter, the fifth insulating layer 22 is formed on the fourth insulating layer 20 and on the common electrode 21 in the openings 19a and 20a. Then, of the fifth insulating layer 22, at least part of the portion located within the openings 19a and 20a is removed to expose the drain electrode 18dB in the opening 22a. As the fifth insulating layer 22, for example, a silicon oxide (SiOx) film, a silicon nitride (SiNx) film, a silicon oxide nitride (SiOxNy: x>y) film or a silicon nitride oxide (SiNxOy: x>y) film may be used as appropriate. The fifth insulating layer 22 is formed of an SiNx film with a thickness of 100 nm.

Then, the pixel electrode 23 is formed so as to be in contact with the drain electrode 18dB in the openings 19a, 20a and 22a. The pixel electrode 23 can be formed by using a transparent conductive film such as an ITO film, an IZO film or a ZnO film. For example, like the common electrode 21, the pixel electrode 23 is formed by using an IZO film with a thickness of 100 nm. As shown in FIG. 1(b), the slit 23s is formed at the pixel electrode 23. In this manner, the TFT substrate 100 of the present embodiment is obtained.

### Second Embodiment

Referring to FIG. 3(a) and FIG. 3(b), the structure of a TFT substrate 200 according to a second embodiment of the present invention will be described. The TFT substrate 200 is different from the TFT substrate 100 according to the first embodiment in the structure of a second TFT 30B for a pixel. Description of the structure other than this is omitted since it is the same as that of the TFT substrate 100. Moreover, the TFT substrate 200 can be easily manufactured only by altering the manufacturing method of the TFT substrate 100.

FIG. 3(a) shows a schematic cross-sectional view of the second TFT 30B for a pixel of the TFT substrate 200, and FIG. 3(b) shows a schematic plan view of the pixel region of the TFT substrate 200.

The TFT substrate 200 is provided with a substrate 32 and the second TFT 30B formed in a display region 202 on the substrate 32. In a driving circuit formation region (not shown) on the substrate 32, the first TFT 10A shown in FIG. 1 is provided.

The second TFT 30B is a bottom gate TFT, and has a gate electrode 35B, a second insulating layer 36 covering the gate electrode 35B, and an oxide semiconductor layer 37 disposed on the second insulating layer 36. Here, the gate electrode 35B is provided on a silicon semiconductor layer 33B formed on the substrate 32 and a first insulating layer 34 covering the silicon semiconductor layer 33B. Like the TFT substrate 100, the silicon semiconductor layer 33B is formed at the same level as the crystalline silicon semiconductor layer of the first TFT (not shown), the first insulating layer 34 serves also as the gate insulating film of the first TFT, and the gate electrode 35B is formed of the same conductive film as the gate electrode of the first TFT. The hitherto described multilayer structure is the same as that of the TFT substrate 100, and the outer periphery of the region where the oxide semiconductor layer 37 and the gate electrode 35B overlap each other is located inside the outer periphery of the silicon semiconductor layer 33B. That is, the silicon semiconductor layer 33B is capable of sufficiently shielding at least the active region of the oxide semiconductor layer 37 from light.

The second TFT 30B is covered with a third insulating layer 39 and a fourth insulating layer 40. On the fourth insulating layer 40, a common electrode 41, a fifth insulating layer 42 and a pixel electrode 43 are formed in this order. The pixel electrode 43 has a slit 43s. More than one slit 43s may be provided. The pixel electrode 43 is in direct contact with the oxide semiconductor layer 37 in the openings 39a, 40a and 42a formed in the third insulating layer 39, the fourth insulating layer 40 and the fifth insulating layer 42. As described above, unlike the TFT substrate 100, the TFT substrate 200 has no drain electrode, and the pixel electrode 43 is in direct contact with the oxide semiconductor layer 37. Since the oxide semiconductor layer 37 is transparent, the portion of contact between the pixel electrode 43 and the oxide semiconductor layer 37 is capable of transmitting light. Therefore, the TFT substrate 200 has an advantage in that the light transmission region LTR is larger and the aperture ratio is higher than those of the TFT substrate 100 having the drain electrode 18dB.

### Third Embodiment

FIG. 4(a) shows a schematic cross-sectional view of a second TFT 50B for a pixel of a TFT substrate 300, and FIG. 4 (b) shows a schematic plan view of the pixel region of the TFT substrate 300.

The TFT substrate 300 is provided with a substrate 52 and the second TFT 50B formed in a display region 302 on the substrate 52. In a driving circuit formation region (not shown) on the substrate 52, the first TFT 10A shown in FIG. 1 is provided.

The second TFT 50B is a bottom gate TFT, and has a gate electrode 55B, a second insulating layer 36 covering the gate electrode 55B, and an oxide semiconductor layer 57 disposed on the second insulating layer 56. Here, the gate electrode 55B is provided on a silicon semiconductor layer 53B formed on the substrate 52 and a first insulating layer 54 covering the silicon semiconductor layer 53B. Like the TFT substrate 100, the silicon semiconductor layer 53B is formed at the same level as the crystalline silicon semiconductor layer of the first TFT (not shown), the first insulating layer 54 serves also as the gate insulating film of the first TFT, and the gate electrode 55B is formed of the same conductive film as the gate electrode of the first TFT. The hitherto described multilayer structure is the same as that of the TFT substrate 100, and the outer periphery of the region where the oxide semiconductor layer 57 and the gate electrode 55B overlap each other is located inside the outer periphery of the silicon semiconductor layer 53B. That is, the silicon semiconductor layer 53B is capable of sufficiently shielding at least the active region of the oxide semiconductor layer 57 from light.

The second TFT 30B is covered with a third insulating layer 59. The TFT substrate 300 does not have the fourth insulating layer 40 that the TFT substrate 200 has. On the third insulating layer 59, a pixel electrode 63, a fourth insulating layer 62 (the fifth insulating layer of the TFT substrate 200) and a common electrode 61 are formed in this order. The common electrode 61 has a plurality of slits 61s.

The pixel electrode 63 is in direct contact with the oxide semiconductor layer 57 in an opening 59a formed in the third insulating layer 59. As described above, like the TFT substrate 200, the TFT substrate 300 has no drain electrode unlike the TFT substrate 100, and the pixel electrode 63 is in direct contact with an oxide semiconductor layer 67. Since the oxide semiconductor layer 67 is transparent, the portion of contact between the pixel electrode 63 and the oxide semiconductor layer 67 is capable of transmitting light. Therefore, the TFT substrate 300 has an advantage in that the light transmission region LTR is larger and the aperture ratio is higher than those of the TFT substrate 100 having the drain electrode 18dB.

Further, on the TFT substrate 300, the fourth insulating layer (planarization layer) 40 that the TFT substrate 200 has is not provided, and the pixel electrode 63 is disposed below the common electrode 61. Therefore, the necessary contact hole for bringing the pixel electrode 63 into contact with the oxide semiconductor layer 67 is only the opening 59a of the third insulating layer 59, and the contact hole is shallow and small. As a consequence, the light transmission region LTR of the TFT substrate 300 is further larger than the light transmission region LTR of the TFT substrate 200, and the aperture ratio is high. Moreover, light leakage of black display due to unevenness of the contact hole can be suppressed, so that display quality can be improved.

The structure where the pixel electrode is disposed below the common electrode (on the side farther from the liquid crystal layer) is also applicable to the TFT substrates 100 and 200.

An FFS mode liquid crystal panel provided with the illustrated TFT substrate 100, 200 or 300 has the TFT substrate 100, 200 or 300 and a counter substrate disposed so as to face the TFT substrate with the liquid crystal layer interposed between the counter substrate and the TFT substrate. The counter substrate has, for example, a light shielding layer and a color filter layer formed on a glass substrate. The light shielding layer is formed, for example, by patterning a Ti film with a thickness of 200 nm into a desired pattern. The color filter layer is formed, for example, by using a photosensitive dry film, and has, for example, R, G and B color filters disposed in correspondence with the pixels. Moreover, there are cases where a photospacer is disposed as required. It is preferable to shield external light incident on the oxide semiconductor layer by using the light shielding layer and/or the color filter layer that the counter substrate has. As such a counter substrate, the counter substrate described in WO 2017/002724 of the present applicant is suitably usable.

Although omitted in the above description, an oriented film is formed on the surfaces of the TFT substrate and the counter substrate that are in contact with the liquid crystal layer. As the oriented film, a known film may be used as appropriate according to the orientation of the liquid crystal layer.

It is to be noted that the TFT substrates according to the embodiments of the present invention are applicable not only to the FFS mode liquid crystal panel shown as an example but also to a vertical electric field mode liquid crystal panel. When it is applied to the vertical electric field mode liquid crystal panel, a common electrode is further provided on the counter substrate. At this time, the common electrode on the TFT substrates 100, 200 and 300 shown as examples is used as an auxiliary capacitance electrode. Detailed descriptions of these alternations are omitted since they are obvious to one of ordinary skill in the art.

While a channel etch TFT is shown as an example in the above-described embodiment, an etch stop TFT may also be used. On the channel etch TFT, for example, as shown in FIG. 1(a), an etch stop layer is not formed in the channel region, and the lower surfaces of the channel side end portions of the source and drain electrodes are disposed so as to be in contact with the upper surface of the oxide semiconductor layer. The channel etch TFT is formed, for example, by forming conductive films for the source and drain electrodes on the oxide semiconductor layer and performing source-drain separation. There are cases where the surface portion of the channel region is etched in the source-drain separation step.

On the other hand, on the TFT where the etch stop layer is formed on the channel region (etch stop TFT), the lower surfaces of the channel side end portions of the source and drain electrodes are located, for example, on the etch stop layer. The etch stop type TFT is formed, for example, by forming an etch stop layer covering the part of the oxide semiconductor layer serving as the channel region, forming conductive films for the source and drain electrodes on the oxide semiconductor layer and the etch stop layer and then, performing source-drain separation.

### INDUSTRIAL APPLICABILITY

The embodiments of the present invention are used for active matrix substrates suitably used for active matrix display devices such as a liquid crystal display device and an organic EL display device, and a method for manufacturing same.

### REFERENCE SIGNS LIST

10A first thin film transistor
10B second thin film transistor
12, 32, 52 substrate
13A crystalline silicon semiconductor layer
13B, 33B, 53B silicon semiconductor layer
13c active region
13d drain region
13s source region
14, 34, 54 first insulating layer
15A, 15B, 35B, 55B gate electrode
16, 36, 56 second insulating layer
17, 37, 57 oxide semiconductor layer
17c active region
17d drain contact region
17s source contact region
18dA drain electrode
18dB drain electrode
18sA source electrode
18sB source electrode
19, 39, 59 third insulating layer
19a, 39a, 59a opening
20, 40 fourth insulating layer
20a, 40a opening
21, 41, 61 common electrode
22, 42, 62 fifth insulating layer
22a, 42a, 62a opening
23, 43, 63 pixel electrode
23s, 43s, 61s slit
100, 200, 300 TFT substrate
100 active matrix substrate
101 driving circuit formation region
102, 202, 302 display region
140 gate driver circuit
150 source driver circuit
170 inspection circuit

1. An active matrix substrate comprising:
a substrate;
a first thin film transistor supported on the substrate and having a first semiconductor layer including crystalline silicon;
a second thin film transistor supported on the substrate and having a second semiconductor layer including an oxide semiconductor; and
a third semiconductor layer including silicon and disposed on the substrate side of the second semiconductor layer of the second thin film transistor with a first insulating layer interposed between the third semiconductor layer and the second semiconductor layer.

2. The active matrix substrate of claim 1, wherein the second thin film transistor further has, on the substrate side of the second semiconductor layer, a gate electrode formed on the first insulating layer and a second insulating layer covering the gate electrode, and
when viewed from a normal direction of the substrate, an outer periphery of a region where the second semiconductor layer and the gate electrode overlap each other is located inside an outer periphery of the third semiconductor layer.

3. The active matrix substrate of claim 1, wherein when viewed from the normal direction of the substrate, an outer periphery of the second semiconductor layer is inside the outer periphery of the third semiconductor layer.

4. The active matrix substrate of claim 2, wherein the first thin film transistor further has a gate electrode disposed so as to face the first semiconductor layer with the first insulating layer interposed between the gate electrode and the first semiconductor layer, and
the gate electrode of the first thin film transistor is formed of the same conductive film as the gate electrode of the second thin film transistor.

5. The active matrix substrate of claim 1, further comprising a pixel electrode formed of a transparent conductive layer, wherein the pixel electrode is in direct contact with the second semiconductor layer.

6. The active matrix substrate of claim 1, wherein the first semiconductor layer includes polycrystalline silicon, and
the third semiconductor layer includes amorphous silicon or polycrystalline silicon.

7. The active matrix substrate of claim 1, wherein the oxide semiconductor includes an In—Ga—Zn—O based semiconductor.

8. The active matrix substrate of claim 1, wherein the second semiconductor layer includes a crystalline In—Ga—Zn—0 based semiconductor.

9. The active matrix substrate of claim 1, wherein the second semiconductor layer has a multilayer structure.

10. The active matrix substrate of claim 1, wherein the second thin film transistor is of a channel-etch type.

11. A method of manufacturing the active matrix substrate of claim 1, the method comprising steps of:
(A) preparing the substrate;
(B) depositing a semiconductor film including silicon on the substrate;
(C) crystallizing at least part of the semiconductor film to form a first semiconductor film including crystalline silicon; and
(D) patterning the semiconductor film to form the first semiconductor layer and the third semiconductor layer, the step (D) including a step of patterning the first semiconductor film to form the first semiconductor layer.
